(19) United States
(12) Patent Application Publication
(10) Pub. No.: US 2007/0090288 A1
(43) Pub. Date: Apr. 26, 2007

(54) METHOD AND SYSTEM FOR ENHANCING RESOLUTION OF A SCANNING ELECTRON MICROSCOPE

(76) Inventor: Dror Shemesh, Hod Hasharon (IL)

Correspondence Address: Patent Counsel, MS/2061;Legal Affairs Dept., Applied Materials, Inc., P. O. Box 450A, Santa Clara, CA, 95052, US

(21) Appl. No.: 11/533,306

(22) Filed: Sep. 19, 2006

Related U.S. Application Data
(60) Provisional application No. 60/728,696, filed on Oct. 20, 2005.

(51) Int. Cl. H01J 37/28

(52) U.S. Cl. 250/305; 250/310; 250/307

(57) ABSTRACT

A method for improving the resolution of a scanning electron microscope, the method includes: defining an energy band in response to an expected penetration depth of secondary electrons in an object; illuminating the object with a primary electron beam; and generating images from electrons that arrive to a spectrometer having an energy within the energy band. A scanning electron microscope that includes: a stage for supporting an object; a controller, adapted to receive or define an energy band an energy band in response to an expected penetration depth of secondary electrons in an object; illumination optics adapted to illuminate the object with a primary electron beam; a spectrometer, controlled by the controller such as to selectively reject electrons in response to the defined energy band; and a processor that is adapted to generate images from detection signals provided by the spectrometer.

### RELATED APPLICATION

This application claims the priority of U.S. provisional patent application Ser. No. 60/728,696, filed on Oct. 20, 2005.

### FIELD OF THE INVENTION

The invention relates to scanning electron microscopes and methods for enhancing the resolution of a scanning electron beam.

### BACKGROUND OF THE INVENTION

Integrated circuits are very complex devices that include multiple layers. Each layer may include conductive material and/or isolating material while other layers may include semi-conductive materials. These various materials are arranged in patterns, usually in accordance with the expected functionality of the integrated circuit. The patterns also reflect the manufacturing process of the integrated circuits.

Integrated circuits are manufactured by complex multi-staged manufacturing processes. This process may include depositing resistive material on a substrate or layer, selectively exposing the resistive material by a photolithographic process, and developing the resistive material to produce a pattern that defines some areas to be later etched or otherwise processed. After the pattern is processed various materials, such as copper are disposed. The deposition step is usually followed by a removing access material. Copper is polished by mechanical means, while other materials can be polished by chemical processes and/or a combination of chemical as well as mechanical processes. The polishing can result in various deformation, such as dishing and erosion.

Various metrology, inspection and failure analysis techniques evolved for inspecting integrated circuits both during the manufacturing stages, between consecutive manufacturing stages, either in combination with the manufacturing process (also termed “in line” inspection techniques) or not (also termed “off line” inspection techniques). It is known that manufacturing failures may affect the electrical characteristics of the integrated circuits. Some of these failures result from unwanted deviations from the required dimensions of the patterns.

Electron beam metrology and defect detection tools, such as Scanning Electron Microscopes are used for high resolution measurement of surface features as well as surface defects and contaminations. These tools generate a spot of electrons that is very small. Typical spots may have a diameter of about few nanometers. The electron beam spot interacts with the surface and with a certain volume that is positioned near to the surface.

FIG. 1 illustrates various interaction processes and various information volumes. An information volume is a space in which an interaction process occurs and result in an emission of X-rays or electrons that may be eventually detected to provide information about the information volume.

The figure illustrates a primary electron beam 111 that hits a sample 100 at an interaction point. As a result, secondary electrons 102 and Auger electrons 104 are emitted from a very thin information volume 103 while back scattered electrons (BSE) 106 and X-rays 108 can leave the inspected object from a volume within the inspected wafer.

It is noted that the distribution of electrons within that volume is not homogenous. The flux of electrons decreases at longer distance from interaction point.

FIG. 1 illustrates that the electrons that are omitted from the object arrive from information volumes that are much wider the secondary electron beam. Accordingly, the effective diameter of spot 115 is responsive to the diameter of the information volumes and is much larger than the diameter 113 of the spot formed on the surface of object 100 by the primary electron beam 111.

For example, when secondary electrons are detected (for example when secondary electron detectors are used) then the volume has a depth that equals secondary electron penetration depth 1 14.

There is a need to provide methods and systems for improving the resolution of scanning electron microscopes.

### SUMMARY OF THE INVENTION

A method for improving the resolution of a scanning electron microscope, the method includes: defining an energy band in response to an expected penetration depth of secondary electrons in an object; illuminating the object with a primary electron beam; and generating images from electrons that arrive to a spectrometer having an energy within the energy band.

A scanning electron microscope that includes: a stage for supporting an object; a controller, adapted to receive or define an energy band an energy band in response to an expected penetration depth of secondary electrons in an object; illumination optics adapted to illuminate the object with a primary electron beam; a spectrometer, controlled by the controller such as to selectively reject electrons in response to the defined energy band; and a processor that is adapted to generate images from detection signals provided by the spectrometer.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1 illustrates interaction process between a sample and a beam of charged particles as well as various information volumes;

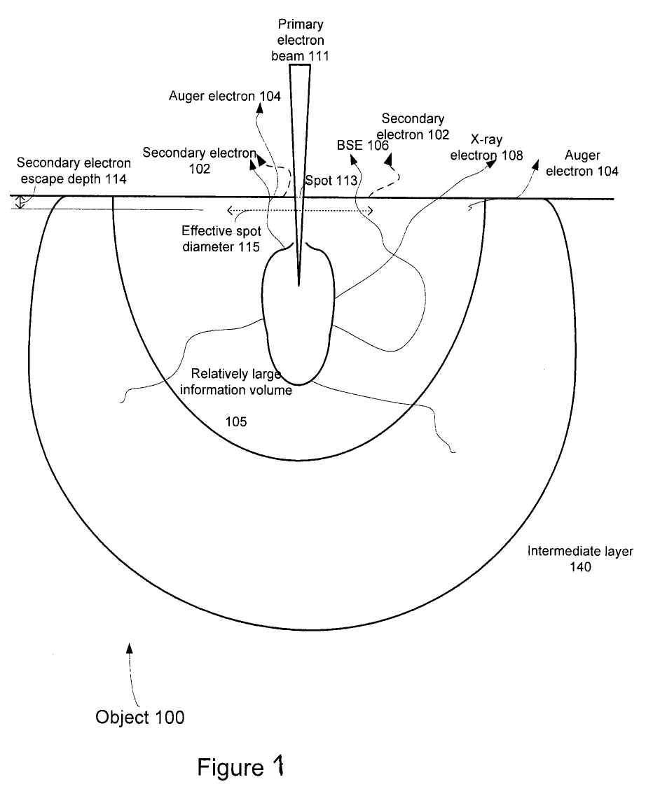

FIG. 2 illustrates the relationship between electron energy and mean free paths of electrons;

FIG. 3 illustrates a Scanning Electron Microscope (SEM) that may be used for process monitoring, according to an embodiment of the invention;

FIG. 4 illustrates the vicinity of the spectrometer, according to an embodiment of the invention;

FIG. 5 illustrates the spectrometer, according to an embodiment of the invention;

FIG. 6 illustrates a method for detecting hidden defects, according to an embodiment of the invention; and

FIG. 7 illustrates an exemplary energy band, according to an embodiment of the invention.

### DETAILED DESCRIPTION OF THE DRAWINGS

The invention relates to systems and methods for improving the resolution of a scanning electron microscope.

The inventors found that by allowing only electrons that are characterized by relatively small mean free path, the effective diameter of the spot (formed as result of an interaction between the primary electron beam and the object) can be dramatically reduced.

The mean free path depends upon the material from object is made of (usually the density of the material) and to one or more characteristics of the primary electron beam. For example, the kinetic energy of the primary electron beam.

For a given material, the mean free path has a minimum at electron energies of about 50V. The mean free path increases as the electron energy is much smaller and much larger that about 50 eV.

By defining a relatively narrow energy band at the vicinity of 50 eV the inventors were able to detect electrons that have a low mean free paths.

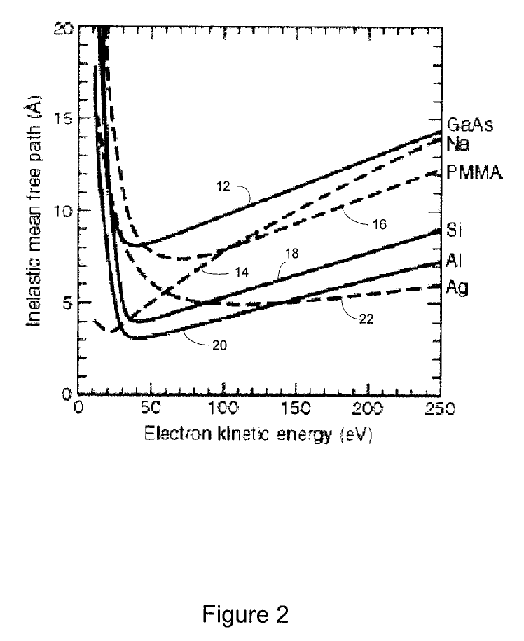

FIG. 2 illustrates the relationship between mean free path and electron energy, in various materials. These relationships are illustrated by curves 10-22. Each curve is related to another material.

Electrons that have energies of about 50 eV convey information from substantially the upper surface of the protective layer.

A Scanning electron microscope generates images of an object under test from secondary electrons that are scattered/omitted from the inspected object. The image is formed from secondary electrons that have various energies, including high-energy electrons (typically limited by the energy of the primary electron beam directed towards the object), low energy electrons (even those having almost zero electron volts) and very low energy electrons.

The inventors found out that an image of substantially the surface of the object and a relatively thin layer beneath that surface (that is thinner and even much thinner than the secondary electron penetration depth 114) can provide a relatively small effective spot diameter 115 and accordingly improve the resolution of SEM 200.

The inventors were able to provide images of the surface and a thin layer of about 1-2 nanometers, which is about one tenth to one fourth of the secondary electron penetration depth. It is noted that other depths and other ratios can be provided, especially by using different energy filter settings.

According to an embodiment of the invention the energy filtering is implemented in a scanning electron microscope that separated between the primary electron beam and the secondary electron beam, such that the filtering of the secondary electron beam does not substantially affect the primary electron beam.

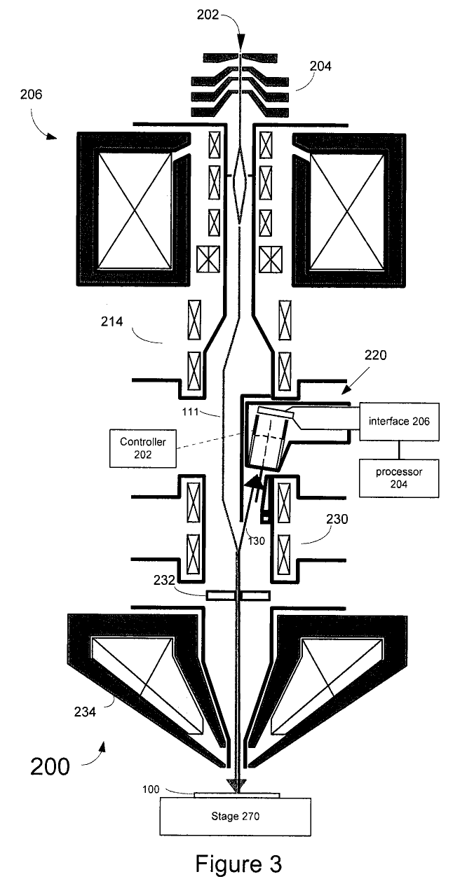

FIG. 3 illustrates a scanning electron microscope (SEM) 200 that may be utilized for reviewing defects, according to an embodiment of the invention.

Scanning electron microscope 200 includes: (i) stage 270, for supporting object 100, the object 100 includes an opaque layer (such as protective layer 130) that positioned above an intermediate layer 140; (ii) controller 202, adapted to receive or define an energy band in response to at least one characteristic of the opaque layer and at least one characteristic of a scanning electron microscope; (iii) illumination optics (that include, for example elements 204, 206, 214, 230 and 234) adapted to illuminate object 100 with primary electron beam 111, (iv) spectrometer 220, controlled by controller 202 such as to selectively reject electrons in response to the defined energy band; and (vii) processor 204 that is adapted to generate images from detection signals provided by the spectrometer.

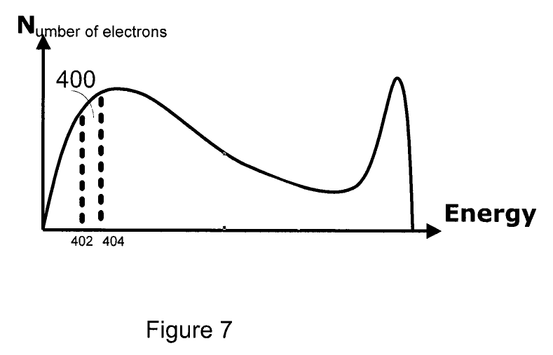

An exemplary energy band 400 is illustrated in FIG. 7. The band includes a minimal energy band level 402 and a maximal energy band level 404.

The processor 204 can receive the detection signals after they have been converted from photons to electric signals and then stored in a location (and a format) accessible to the processor 204. This conversion and storage can be executed by interface 206.

SEM 200 includes an electron gun 202 for generating a primary electron beam 111, as well as multiple control and voltage supply units (not shown), a condenser lens 204, a group of lenses 206 that include aperture lens, aperture alignment and a sitgmator. A final aperture is defined between these lenses.

These lenses are followed by four deflectors four additional deflectors 214(1)-214(4) (collectively denoted 214) that cause the primary electron beam 111 to deviate from the optical axis 260 of SEM 200, while propagating in parallel to that axis. This can be achieved by two deflections.

These lenses are followed by four additional deflectors 230(1)-230(4) (collectively denoted 230) that cause the primary electron beam 111 to return to propagate along the optical axis 260 of SEM 200. This can be achieved by two deflections. Each pair of deflectors causes the primary electron beam to de deflected.

These deflectors are followed by an in-lens detector 232 and an objective (as well as electrostatic) lens 234.

It is noted that SEM 200 may include more than a single detector. SEM 200 may include at least one detector positioned in-lens and/or at least one external detector (not shown). SEM 200 may include detectors of various types, such as a secondary electron detector, a backscattered electron detector, a narrowband X-ray detector, and the like. Each detector can include a single sensing element, or may include an array of sensing elements. The detectors may be positioned to detect radiation emitted towards different directions.

In SEM 200 the primary electron beam 111 is directed through an aperture within the in-lens detector 232 to be focused by the objective lens 234 onto an inspected object 100. The primary electron beam 111 interacts with object 100 and as a result various types of electrons and photons, such as secondary electrons, back-scattered electrons, Auger electrons and X-ray quanta are reflected or scattered.

These reflected and scattered electrons (or at least a part of these electrons) form a secondary electron beam that moved upwards towards the in-lens detector 232. Some electrons are detected by the in-lens detector while some propagate towards spectrometer 220.

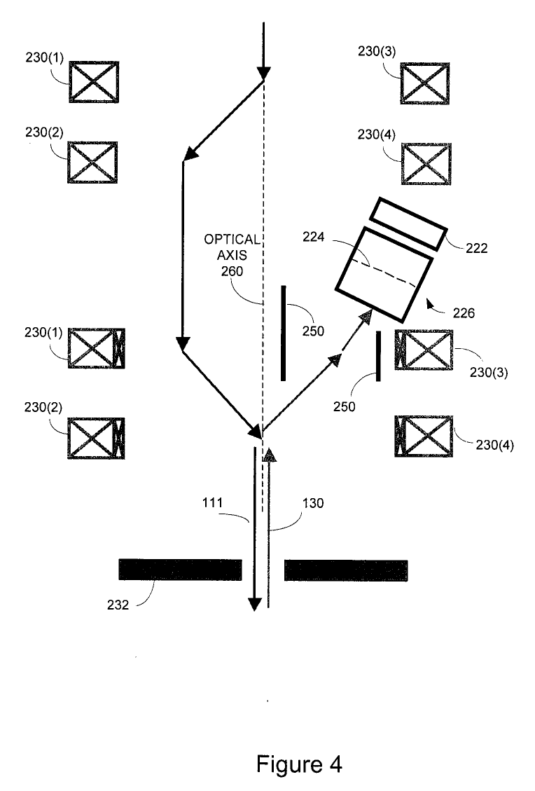

FIG. 4 illustrates an optional booster 250 that attracts these electrons toward the spectrometer 20. This booster 250 enabled to place a relatively large spectrometer 220 within SEM 200, while positioning it relatively far from the SEM optical axis 260. This distance was introduced in order to reduce the affect of the energy filter 224 within spectrometer 220 on the primary electron beam 111.

It is noted that the separation between the primary and secondary electron beam can be achieved by enhancing the deflection fields applied by deflectors 230 and 214. This can be applied in addition to the booster 250 or instead of such a booster 250.

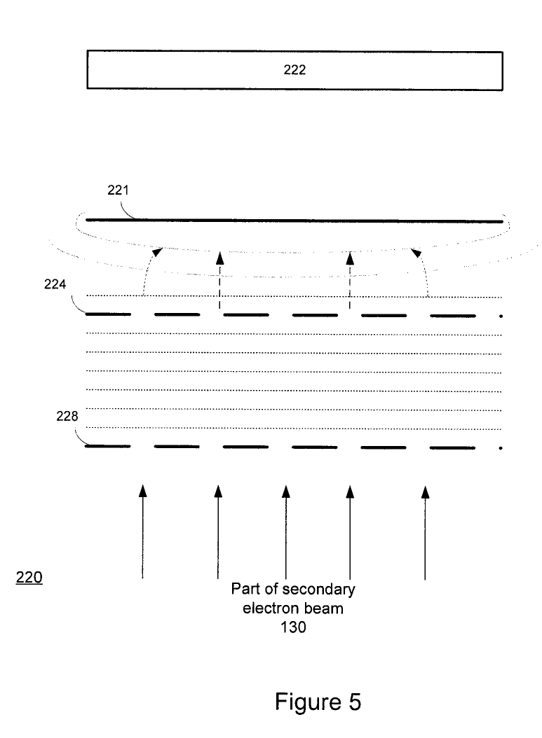

According to an embodiment of the invention the affect of the energy filter can be reduced by placing an input grid 228 that is set to a potential difference that masks the electrostatic fields introduced by the energy filter grid 224. The inventors set the input grid 228 to the voltage of the column (about 8 Kv till 9 Kv), but other voltages can be applied. This arrangement is illustrated in FIG. 5. Equi-potential lines are illustrated by fine dashed lined. The grids 228 and 224 are illustrated by coarser dashed lines.

FIG. 5 further illustrates the detecting surface 221 of spectrometer 220. This surface 221 emits electrons that are converted to photons by scintillator 222. The light emitted from the scintillator 222 is provided by a light guide (not shown) to a light sensor that provided signals that can be used to generate an image.

The vertical arrows as well as the curved arrows illustrate electrons that arrive to the spectrometer 220. Some propagate towards the detecting surface 221 while others are rejected.

The spectrum of the secondary electron beam or a selected band can be reconstructed by gradually changing the voltage supplied to grid 224.

In order to generate an image of the intermediate layer (and especially its upper surface) the selected energy band 400 is defined by a minimal energy band level 402 and by a maximal energy band level 403.

These energy levels (402 and 404) can be calculated in advance, in view of the material from which the protective layer is made an in view of the operation characteristics (for example voltage difference between the object and the column of SEM 200) of SEM 200. These energy levels can be measured in advance, after various images of the object or a similar object are acquired.

It is noted that the operator can adjust these energy levels by applying different energy levels and monitoring the acquired SEM images.

Electrons that have an energy that is lower than the minimal energy band level 404 are blocked by applying a voltage that corresponds to that minimal energy band level to grid 224. After the grid is set to such a voltage a first (or more) minimal energy band level images are acquired.

In order to filter out the information provided by electrons that have energies that are above the maximal energy band level 404 the grid is set to voltage that corresponds to the maximal energy band level 404. The one or more additional maximal energy band level images are acquired.

Differential images reflecting information conveyed by electrons that have an energy within the energy band are acquired by subtracting one or more maximal energy band level image from one or more corresponding minimal energy band level images.

It is noted that the maximal energy band level 404 can be set in order to receive information from the surface of the intermediate layer and not from locations beneath that surface.

Object 100 is positioned on stage 270. During the process monitoring a relative movement is introduced between object 100 and the primary electron beam 111. This may involve mechanical movement of the object, mechanical movement of other parts of SEM 200 and/or electrical deflection of the beam 111, or a combination of movements and deflection. Typically, the mechanical movement is introduced when a certain target or a certain area are being located, but it may also be introduced while scanning said target or area.

When a certain target or area has to be inspected, there is a need to locate that certain target or area. Various well-known locating processes are known in the art and can be applied. The locating process may include: (i) introducing a mechanical movement towards a vicinity of that certain target or area, (ii) acquiring an image of said vicinity (usually using a field of view that is derived from mechanical movement inaccuracies) by scanning said vicinity within an acquisition window, (iii) processing the image to locate the target or area (for example, comparing a target by comparison with a previously acquired target image) to locate the target or area. Usually, once the location process ends the images of the area are acquired by scanning it with a scanning window that is usually much smaller than the acquisition window.

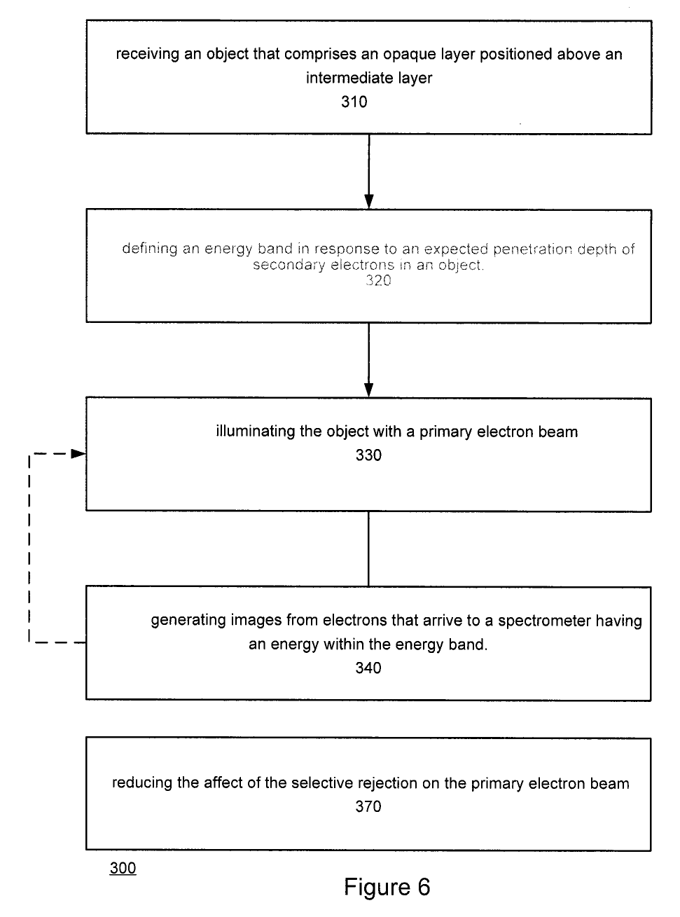

FIG. 6 illustrates method 300 for detecting hidden defects, according to an embodiment of the invention.

Method 300 starts by stage 310 of receiving an object that comprises an opaque layer positioned above an intermediate layer.

Stage 310 is followed by stage 320 of defining an energy band in response to an expected penetration depth of secondary electrons in an object. The definition is usually also responsive to the spot formed by the primary electron beam on the surface of the inspected object and to a required effective resolution. It is noted that stage 320 can precede stage 310 and that the definition can be applied to multiple objects.

Stage 320 is followed by stage 330 of illuminating the object with a primary electron beam. This stage can include locating a certain area or target.

Stage 330 is followed by stage 340 of generating images from electrons that arrive to a spectrometer having an energy level within the energy band.

Conveniently, stage 340 can include adjusting the energy band in response to one or more generated images.

Stage 340 conveniently includes selectively rejecting electrons based upon their energy.

Method 300 can further include stage 370 of reducing the affect of the selective rejection on the primary electron beam. Stage 370 can be applied during stages 330-340. Stage 370 can include attracting secondary electrons towards a spectrometer by applying an attraction field. Stage 370 may include placing an input grid at the input of a spectrometer and setting the grid to a voltage that corresponds to the voltage of the environment of the spectrometer, and especially to the voltage of the SEM column. Stage 370 may also include separating between the primary electron beam and a secondary electron beam formed from an interaction between the primary electron beam and the object.

According to an embodiment of the invention the energy band is defined by a minimal energy band level and a maximal energy band level.

Conveniently, stage 340 includes generating minimal energy band level images. According to an embodiment of the invention stage 340 includes generating maximal energy band level images. Conveniently, stage 340 includes generating comprises generating minimal energy band level images, generating maximal energy band level images and subtracting the maximal energy band level images from the minimal energy band level images to provide the images from electrons that arrive to a spectrometer having an energy within the energy band.

The present invention can be practiced by employing conventional tools, methodology and components. Accordingly, the details of such tools, component and methodology are not set forth herein in detail. In the previous descriptions, numerous specific details are set forth, such as shapes of cross sections of typical lines, amount of deflection units, etc., in order to provide a thorough understanding of the present invention. However, it should be recognized that the present invention might be practiced without resorting to the details specifically set forth.

Only exemplary embodiments of the present invention and but a few examples of its versatility are shown and described in the present disclosure. It is to be understood that the present invention is capable of use in various other combinations and environments and is capable of changes or modifications within the scope of the inventive concept as expressed herein.

We claim:

1. A method for improving the resolution of a scanning electron microscope, the method comprising the stages of:
defining an energy band in response to an expected penetration depth of secondary electrons in an object;
illuminating the object with a primary electron beam; and
generating images from electrons that arrive to a spectrometer having an energy within the energy band.

2. The method according to claim 1 further comprising adjusting the energy band in response to one or more generated images.

3. The method according to claim 1 whereas the defining is responsive to the material from which the object is made is made of and a diameter of the primary electron beam.

4. The method according to claim 1 whereas the generating comprising selectively rejecting electrons based upon their energy.

5. The method of claim 1 further comprising reducing the affect of the selective rejection on the primary electron beam.

6. The method according to claim 1 whereas the generating comprises attracting secondary electrons towards a spectrometer by applying an attraction field.

7. The method according to claim 1 further comprising separating between the primary electron beam and a secondary electron beam formed from an interaction between the primary electron beam and the object.

8. The method according to claim 1 whereas the generating comprises generating minimal energy band level images.

9. The method according to claim 1 whereas the generating comprises generating maximal energy band level images.

10. The method according to claim 1 whereas the generating comprises generating minimal energy band level images, generating maximal energy band level images; and subtracting the maximal energy band level images from the minimal energy band level images to provide the images from electrons that arrive to a spectrometer having an energy within the energy band.

11. A scanning electron microscope, comprising:
a stage for supporting an object;
a controller, adapted to receive or define an energy band an energy band in response to an expected penetration depth of secondary electrons in an object;
illumination optics adapted to illuminate the object with a primary electron beam;
a spectrometer, controlled by the controller such as to selectively reject electrons in response to the defined energy band; and
a processor that is adapted to generate images from detection signals provided by the spectrometer.

12. The scanning electron microscope according to claim 11 whereas the controller is further adapted to adjust the energy band in response to one or more generated images.

13. The scanning electron microscope according to claim 11 whereas the controller is adapted to define the energy band in response to an expected penetration depth of secondary electrons in an object.

14. The scanning electron microscope of claim 11 further adapted to reduce an affect of the selective rejection on the primary electron beam.

15. The scanning electron microscope according to claim 11 further comprising a booster adapted to attract secondary electrons towards the spectrometer.

16. The scanning electron microscope according to claim 11 further comprising multiple deflectors adapted to separate between the primary electron beam and a secondary electron beam formed from an interaction between the primary electron beam and the object.

17. The scanning electron microscope according to claim 11 further comprising a spectrometer input grid that is set to a voltage that corresponds to a voltage level of an environment of the spectrometer.

18. The scanning electron microscope according to claim 11 further adapted to generate minimal energy band level images.

19. The scanning electron microscope according to claim 11 further adapted to generate maximal energy band level images.

20. The scanning electron microscope according to claim 11 further adapted to generate minimal energy band level images, generate maximal energy band level images; and subtract the maximal energy band level images from the minimal energy band level images to provide images from electrons that arrive to a spectrometer having an energy within the energy band.
